(19) United States
(12) Patent Application Publication
(10) Pub. No.: US 2016/0172210 A1
(43) Pub. Date: Jun. 16, 2016

(54) SEMICONDUCTOR MANUFACTURING APPARATUS AND SEMICONDUCTOR MANUFACTURING METHOD

(71) Applicant: KABUSHIKI KAISHA TOSHIBA, Minato-ku (JP)

(72) Inventor: Noriyuki ASAMI, Yokkaichi (JP)

(73) Assignee: KABUSHIKI KAISHA TOSHIBA, Minato-ku (JP)

(21) Appl. No.: 14/644,445

(22) Filed: Mar. 11, 2015

Related U.S. Application Data
(60) Provisional application No. 62/090,588, filed on Dec. 11, 2014.

(51) Int. Cl. H01L 21/311; H01L 21/02; H01J 37/32; H01L 21/67

(52) U.S. Cl. CPC H01L 21/31116; H01L 21/67069; H01L 21/02274; H01J 37/3244

(57) ABSTRACT

In one embodiment, a semiconductor manufacturing apparatus includes a wafer setting module including an upper face provided with one or more openings, a wafer being to be set on the upper face. The apparatus further includes a first particle supply module configured to supply first particles from the openings to an end portion of the wafer set on the wafer setting module to remove a film formed on the end portion of the wafer by using the first particles.

### CROSS REFERENCE TO RELATED APPLICATION

This application is based upon and claims the benefit of priority from the prior U.S. Provisional Patent Application No. 62/090,588 filed on Dec. 11, 2014, the entire contents of which are incorporated herein by reference.

### FIELD

Embodiments described herein relate to a semiconductor manufacturing apparatus and a semiconductor manufacturing method.

### BACKGROUND

In a case of forming a film on a wafer, if the film remains at a bevel (end portion) of the wafer, the film remaining at the bevel may become a dust source. An example of such a film is an amorphous carbon film formed by plasma enhanced chemical vapor deposition (PECVD). In some cases, the film is formed on the wafer in a state that the bevel is covered with a shadow ring in order to prevent the film from being formed at the bevel. This enables the film to be formed on a surface of the wafer excluding the bevel. This is referred to as bevel cut. In these cases, when the wafer moves on a stage, there may be a problem that a positional relation between the bevel and the shadow ring becomes unstable and therefore a position of the bevel cut becomes unstable.

### BRIEF DESCRIPTION OF THE DRAWINGS

FIGS. 1A and 1B are a sectional view and a top view illustrating a structure of a semiconductor manufacturing apparatus of a first embodiment;

FIGS. 2A and 2B are sectional views illustrating an operation of the semiconductor manufacturing apparatus of the first embodiment;

FIG. 3 is a sectional view illustrating a structure of a semiconductor manufacturing apparatus of a comparative example of the first embodiment;

FIGS. 4A to 4C are sectional views illustrating a preferred processing example and non-preferred examples of a wafer of the first embodiment;

FIG. 5 is a flowchart illustrating a semiconductor manufacturing method of the first embodiment;

FIGS. 6A and 6B are a sectional view and a top view illustrating a structure of a semiconductor manufacturing apparatus of a second embodiment; and

FIGS. 7A and 7B are a sectional view and a top view illustrating a structure of a semiconductor manufacturing apparatus of a third embodiment.

### DETAILED DESCRIPTION

Embodiments will now be explained with reference to the accompanying drawings.

In one embodiment, a semiconductor manufacturing apparatus includes a wafer setting module including an upper face provided with one or more openings, a wafer being to be set on the upper face. The apparatus further includes a first particle supply module configured to supply first particles from the openings to an end portion of the wafer set on the wafer setting module to remove a film formed on the end portion of the wafer by using the first particles.

### First Embodiment

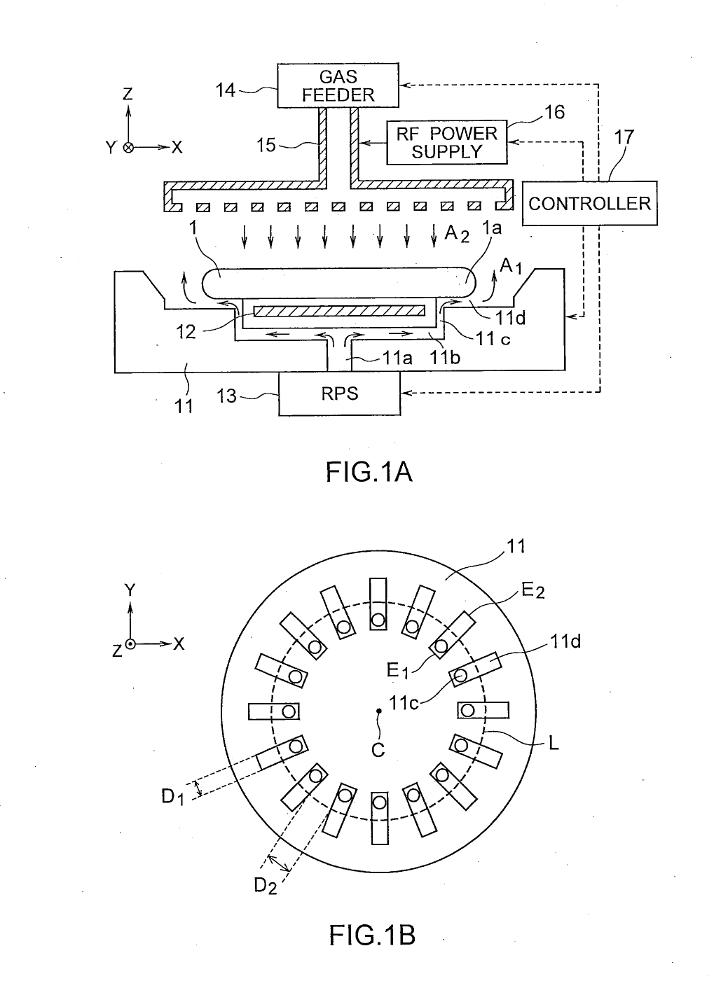

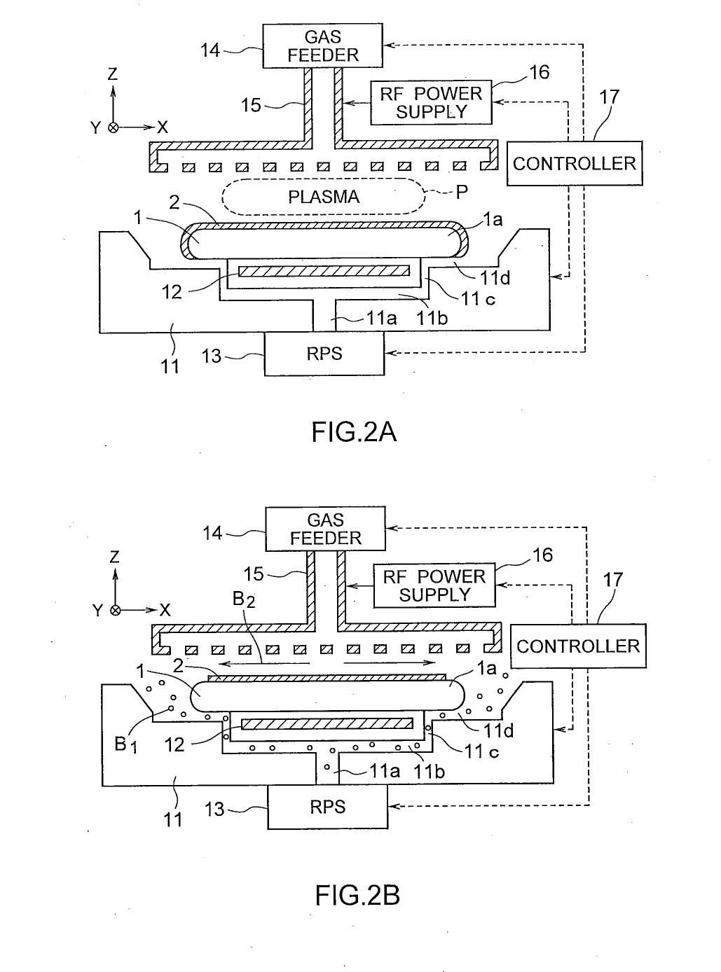

FIGS. 1A and 1B are a sectional view and a top view illustrating a structure of a semiconductor manufacturing apparatus of a first embodiment. FIGS. 2A and 2B are sectional views illustrating an operation of the semiconductor manufacturing apparatus of the first embodiment.

The semiconductor manufacturing apparatus of the present embodiment will be described below with reference to mainly FIGS. 1A and 1B. FIGS. 2A and 2B will also be referenced as appropriate in the description.

As illustrated in FIGS. 1A and 1B, the semiconductor manufacturing apparatus of the present embodiment includes a stage 11, an electrode plate 12, a remote plasma system (RPS) 13, a gas feeder 14, a face plate 15, a radio frequency (RF) power supply 16 and a controller 17. The stage 11 is an example of a wafer setting module. The RPS 13 is an example of a first particle supply module. The gas feeder 14, the face plate 15, the RF power supply 16 and the electrode plate 12 are an example of a second particle supply module.

As illustrated in FIG. 2A, the semiconductor manufacturing apparatus of the present embodiment can form a film 2 on a wafer 1. An example of the wafer 1 is a semiconductor wafer such as a silicon wafer. An example of the film 2 is an amorphous carbon film. An example of a process to form the film 2 is a deposition process such as PECVD. The film 2 may be formed directly on the wafer 1 or formed on the wafer 1 through another layer.

As illustrated in FIG. 2B, the semiconductor manufacturing apparatus of the present embodiment can also remove the film 2 formed at a bevel 1a of the wafer 1. An example of a process to remove the film 2 is an etching process. In this way, the semiconductor manufacturing apparatus of the present embodiment can perform a bevel cut on the wafer 1. The bevel 1a of the wafer 1 is an example of an end portion of the wafer 1.

The structure of the semiconductor manufacturing apparatus of the present embodiment will be described below with reference to mainly FIGS. 1A and 1B.

[Stage 11]

The stage 11 includes a hole 11a provided at a lower face of the stage 11, a cavity 11b connected to the hole 11a, a plurality of holes 11c connected to the cavity 11b, and a plurality of grooves 11d provided at an upper face of the stage 11 and connected to the holes 11c. The wafer 1 is set on the upper face of the stage 11. The grooves 11d are an example of one or more openings.

FIGS. 1A and 1B illustrate an X direction and a Y direction that are parallel to the upper and lower faces of the stage 11 and perpendicular to each other, and a Z direction perpendicular to the upper and lower faces of the stage 11. In the present specification, a +Z direction is treated as an upward direction while a −Z direction is treated as a downward direction. The stage 11 and the RPS 13 are in a positional relationship where the RPS 13 is positioned below the stage 11. The −Z direction of the present embodiment may or may not correspond with the direction of gravity.

FIG. 1B illustrates the upper face of the stage 11. The grooves 11d extend radially with respect to a predetermined center point C on the upper face of the stage 11. The upper face of the stage 11 of the present embodiment has a circular shape, and the point C corresponds to the center of the circle. Reference numerals E₁ and E₂ indicate an inner end portion and an outer end portion of each groove 11d, respectively. Each hole 11c of the present embodiment is provided near the inner end portion E₁ of a groove 11d.

A reference numeral L indicates an outline of the wafer 1 set on the upper face of the stage 11. The wafer 1 of the present embodiment may be set such that the center of the wafer 1 overlaps with the center C of the stage 11 or may be set such that the center of the wafer 1 deviates to some degree from the center C of the stage 11. The wafer 1 illustrated in FIG. 1B is set such that the center of the wafer 1 overlaps with the center C of the stage 11.

The wafer 1 of the present embodiment is desirably set on the upper face of the stage 11 such that each groove 11d of the stage 11 includes a region (first region) covered with the wafer 1 and a region (second region) not covered with the wafer 1. An example of the first region is the inner end portion E₁ of each groove 11d, and an example of the second region is the outer end portion E₂ of each groove 11d. The wafer 1 illustrated in FIG. 1B is set such that the inner end portion E₁ of each groove 11d is covered with the wafer 1 while the outer end portion E₂ of each groove 11d is not covered with the wafer 1. In other words, the wafer 1 of the present embodiment may be set such that the center of the wafer 1 deviates from the center C of the stage 11 as long as the inner end portion E₁ is covered with the wafer 1 and the outer end portion E₂ is not covered with the wafer 1.

Accordingly, in the present embodiment, the distance between the point C and the inner end portion E₁ of each groove 11d is set smaller than the radius of the wafer 1. Moreover, the distance between the point C and the outer end portion E₂ of each groove 11d is set larger than the radius of the wafer 1. The radius of the wafer 1 is 150 mm, for example.

A reference numeral D₁ indicates the width of the grooves 11d in a circumferential direction. The width D₁ is 1 mm, for example. A reference numeral D₂ indicates a distance between the grooves 11d adjacent to each other in the circumferential direction. The distance D₂ is 4 mm, for example. Any number of the grooves 11d may be provided on the upper face of the stage 11 as long as the bevel cut can be performed well.

[Electrode Plate 12]

The electrode plate 12 is provided within the stage 11. The electrode plate 12 together with the face plate 15 (to be described) function as a pair of electrodes generating plasma. The electrode plate 12 functions as a lower electrode, and the face plate 15 functions as an upper electrode.

[RPS 13]

The RPS 13 generates radicals such as oxygen radicals and nitrogen trifluoride radicals. The radicals are an example of first particles.

As indicated with an arrow A₁, the radicals generated by the RPS 13 are discharged to the hole 11a, sent to the grooves 11d through the cavity 11b and the holes 11c, and supplied from the grooves 11d to the wafer 1 set on the stage 11. At this time, since the bevel 1a of the wafer 1 is located near the grooves 11d, the radicals are supplied from the grooves 11d to the bevel 1a. As a result, the film 2 formed at the bevel 1a is etched by the radicals and removed (FIG. 2B).

The radicals may possibly become inactive when the diameter of the holes 11c and the width of the grooves 11d are small. It is therefore desired that the diameter of the holes 11c and the width of the grooves 11d of the present embodiment be set to values which can sufficiently prevent the radicals from becoming inactive.

The RPS 13 may also supply the plasma in addition to the radicals from the grooves 11d to the wafer 1 set on the stage 11. The plasma is an example of the first particles as well.

[Gas Feeder 14, Face Plate 15, RF Power Supply 16]

The gas feeder 14, the face plate 15, the RF power supply 16 and the electrode plate 12 supply plasma to the wafer 1 set on the stage 11 as indicated with an arrow A₂. The film 2 is formed on the wafer 1 by the plasma as a result (FIG. 2A). The plasma is an example of second particles.

The gas feeder 14 supplies a second gas that is a source gas of the plasma, when the film 2 is formed on the wafer 1 with the plasma. The second gas can be a hydrocarbon gas such as a methane (CH₄) gas, an acetylene (C₂H₂) gas, and a propylene (C₃H₆) gas. These hydrocarbon gases can be used when forming the amorphous carbon film as the film 2, for example.

The second gas is supplied above the wafer 1 from a plurality of gas supply ports provided at the lower face of the face plate 15. The RF power supply 16 at this time applies a radio frequency voltage between the face plate 15 and the electrode plate 12. As a result, the second gas becomes the plasma, by which the film 2 is formed on the wafer 1.

The gas feeder 14 further supplies a first gas to the surface of the film 2 when using the radicals to remove the film 2 formed on the wafer 1 (FIG. 2B). The first gas can be an inert gas such as a nitrogen (N₂) gas and a halogen gas. The first gas is supplied to the surface of the film 2 from the plurality of gas supply ports provided at the lower face of the face plate 15.

The first gas is supplied to prevent the radicals from reaching the surface of the film 2 apart from the bevel 1a. As a result, the radicals are supplied mainly to the film 2 near the bevel 1a. Accordingly, the film 2 formed at the bevel 1a can be removed while leaving the film 2 formed outside the bevel 1a, according to the present embodiment.

The stage 11, the electrode plate 12, the RPS 13, the gas feeder 14, the face plate 15 and the RF power supply 16 of the present embodiment are disposed within the same chamber or near the chamber of the semiconductor manufacturing apparatus.

[Controller 17]

The controller 17 controls various operations of the semiconductor manufacturing apparatus. The controller 17 controls supply of the radicals from the RPS 13, supply of the first and second gases from the gas feeder 14, and application of the radio frequency voltage by the RF power supply 16.

The controller 17 can further control the distance between the gas supply ports at the lower face of the face plate 15 and the upper face of the stage 11 by moving up/down the stage 11. The controller 17 can therefore move the wafer 1 closer to the face plate 15 or farther from the face plate 15.

The controller 17 of the present embodiment sets the distance between the face plate 15 and the stage 11 shorter at the time of the etching process illustrated in FIG. 2B than the distance between the face plate 15 and the stage 11 at the time of the deposition process illustrated in FIG. 2A. This allows the first gas to be supplied near the center of the wafer 1, effectively preventing the radicals from reaching the surface of the film 2 apart from the bevel 1a.

The deposition process and the etching process performed by the semiconductor manufacturing apparatus of the present embodiment will be described with reference to FIGS. 2A and 2B.

In the deposition process illustrated in FIG. 2A, the gas feeder 14 supplies the second gas while the RF power supply 16 applies the radio frequency voltage between the face plate 15 and the electrode plate 12. As a result, the second gas becomes the plasma as indicated with a reference numeral P, whereby the film 2 is formed on the wafer 1.

After completing the deposition process, the controller 17 of the present embodiment moves up the stage 11 before starting the etching process.

In the etching process illustrated in FIG. 2B, the RPS 13 supplies the radicals from the grooves 11d to the bevel 1a of the wafer 1 set on the stage 11. A reference numeral B₁ indicates the radicals supplied from the RPS 13. At this time, the gas feeder 14 supplies the first gas to the surface of the film 2 as indicated with an arrow B₂ to prevent the radicals from reaching the surface of the film 2 apart from the bevel 1a. The film 2 formed at the bevel 1a is therefore removed while leaving the film 2 formed outside the bevel 1a.

As described above, the semiconductor manufacturing apparatus of the present embodiment includes the stage 11 having the upper face on which the plurality of grooves 11d are provided and on which the wafer 1 is to be set. The semiconductor manufacturing apparatus of the present embodiment removes the film 2 formed at the bevel 1a by supplying the radicals from these grooves 11d to the bevel 1a of the wafer 1 set on the stage 11.

According to the present embodiment, the radicals from the grooves 11d can be brought into contact with the bevel 1a even when the wafer 1 moves on the stage 11 or the center of the wafer 1 deviates from the center C of the stage 11. When the center of the wafer 1 deviates from the center C of the stage 11, for example, the radicals can be brought into contact with each portion of the bevel 1a of the wafer 1 as long as the outer end portion E₂ of each groove 11d is not covered with the wafer 1. As a result, according to the present embodiment, the position of the bevel cut on the wafer 1 can be stabilized regardless of the installed position of the wafer 1.

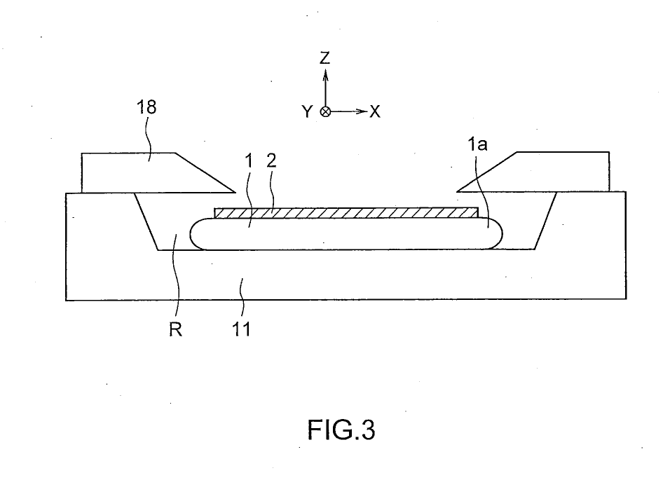

FIG. 3 is a sectional view illustrating a structure of a semiconductor manufacturing apparatus of a comparative example of the first embodiment.

In this comparative example, the film 2 is formed on the wafer 1 in a state that the bevel 1a is covered with a shadow ring 18 in order to prevent the film 2 from being formed at a bevel 1a. However, the stage 11 usually has a play region R near the bevel 1a of the wafer 1 in order for the wafer 1 to be conveyed easily. The wafer 1 of this comparative example may therefore move on the stage 11 because of the play region R. Accordingly, the positional relation between the bevel 1a and the shadow ring 18 is unstable in this comparative example, and therefore the position of the bevel cut becomes unstable.

On the other hand, such problem can be resolved in the present embodiment where the bevel cut is performed by using the groove 11d provided on the stage 11.

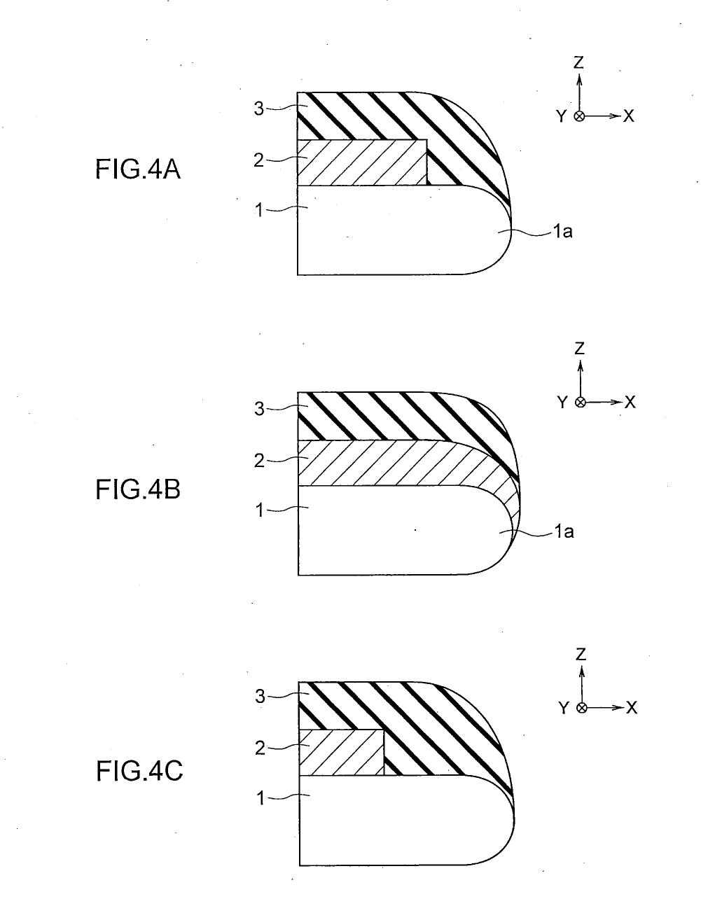

FIGS. 4A to 4C are sectional views illustrating a preferred processing example and non-preferred examples of the wafer 1 of the first embodiment.

FIG. 4A illustrates the preferable example of how the wafer 1 is processed. FIG. 4A illustrates the wafer 1, the bevel-cut film 2 formed on the wafer 1, and a film 3 formed on the wafer 1 to cover the film 2. An example of the film 3 is a dielectric anti-refrective coating (DARC).

FIGS. 4B and 4C illustrate the unpreferable examples of how the wafer 1 is processed. The film 2 illustrated in FIG. 4B is not bevel cut. In this case, the film 2 formed at the bevel 1a may possibly be the dust source. The film 2 illustrated in FIG. 4C is bevel cut excessively.

The present embodiment can avoid the formation of the film 2 as illustrated in FIG. 4B by performing the bevel cut while using the groove 11d provided on the stage 11. Moreover, the present embodiment can avoid the formation of the film 2 as illustrated in FIG. 4C by supplying the first gas at the time of the etching process.

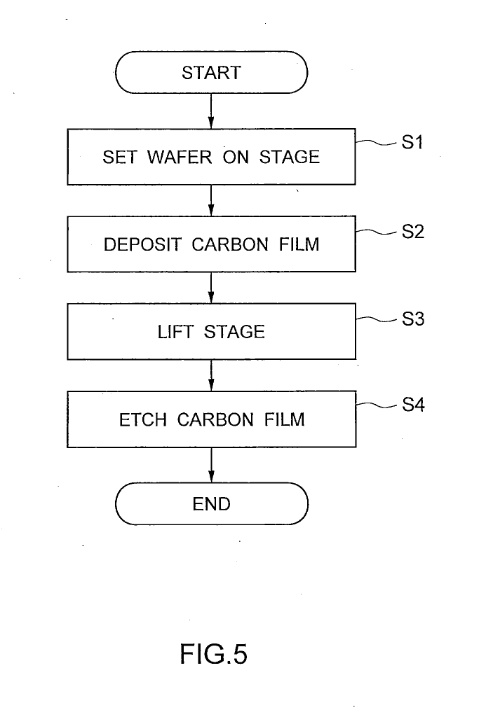

FIG. 5 is a flowchart illustrating a semiconductor manufacturing method of the first embodiment.

First, the wafer 1 is brought into a chamber of the semiconductor manufacturing apparatus and set on the upper face of the stage 11 (step S1). It is desired at this time that the wafer 1 be set such that the inner end portion E₁ of each groove 11d is covered with the wafer 1 while the outer end portion E₂ of each groove 11d is not covered with the wafer 1.

Next, the plasma is supplied to the wafer 1 set on the stage 11 to deposit the film 2 on the wafer 1 (step S2). The film 2 can be an amorphous carbon film, for example. The stage 11 is then moved up to bring the wafer 1 closer to the face plate 15 (step S3). Next, the radicals are supplied from the grooves 11d to the bevel 1a of the wafer 1 set on the stage 11, thereby etching the film 2 deposited at the bevel is (step S4).

The bevel-cut film 2 is formed as a result. The film 3 may be thereafter formed on the wafer 1 through the film 2.

As described above, according to the present embodiment, the position of the bevel cut on the wafer 1 can be stabilized by providing the plurality of grooves 11d on the upper face of the stage 11 and removing the film 2 formed at the bevel 1a of the wafer 1 while using the radicals from the grooves 11d.

The semiconductor manufacturing apparatus of the present embodiment may also be adapted to form the film 2 on the wafer 1 in a chamber different from the chamber illustrated in FIG. 1A and then remove the film 2 at the bevel 1a of the wafer 1 in the chamber illustrated in FIG. 1A. That is, the semiconductor manufacturing apparatus of the present embodiment may be adapted to perform both the deposition process and the etching process in the chamber illustrated in FIG. 1A or perform only the etching process in the chamber illustrated in FIG. 1A. The same can be said of second and third embodiments described below.

### Second Embodiment

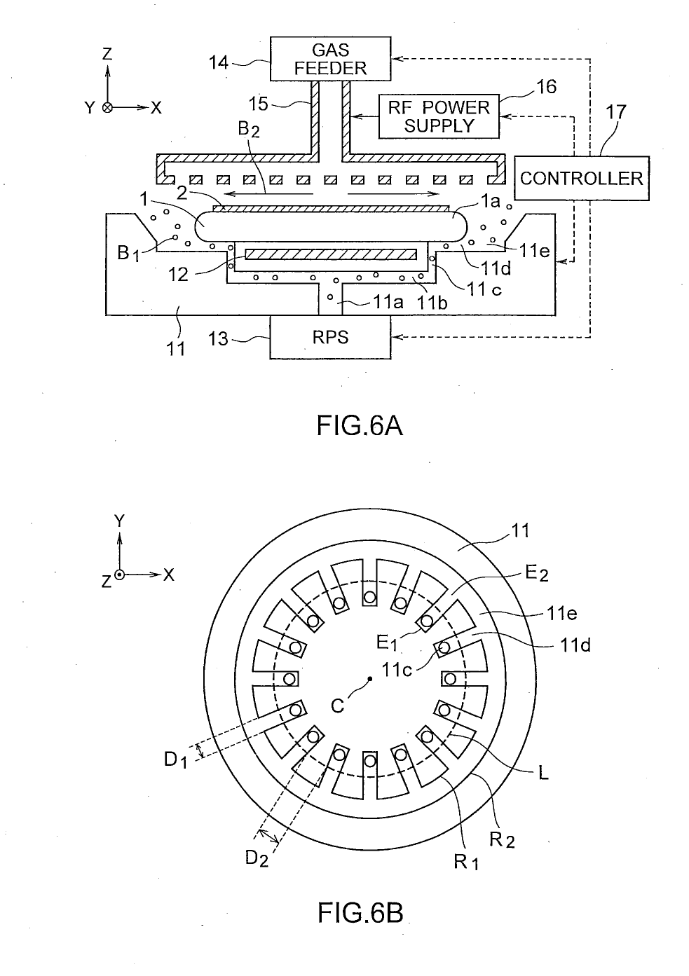

FIGS. 6A and 6B are a sectional view and a top view illustrating a structure of a semiconductor manufacturing apparatus of a second embodiment.

Similar to the first embodiment, the stage 11 of the present embodiment includes a hole 11a, a cavity 11b, a plurality of holes 11c and a plurality of grooves 11d. The stage 11 of the present embodiment further includes an annular groove 11e.

FIG. 6B illustrates the upper face of the stage 11. The annular groove 11e is provided on the upper face of the stage 11, connected to outer end portions E₂ of the grooves 11d, and extends annularly. The grooves 11d and annular groove 11e are examples of one or more openings.

Reference numerals R₁ and R₂ indicate an inner end portion and an outer end portion of the annular groove 11e, respectively. Each of the end portions R₁ and R₂ of the present embodiment has a circular shape with respect to a center point C. The radius of each of the end portions R₁ and R₂ of the present embodiment is set larger than the radius of a wafer 1.

The annular groove 11e is provided on the upper face of the stage 11 in the present embodiment, whereby radicals can be evenly brought into contact with a bevel 1a of the wafer 1. Therefore, according to the present embodiment, the bevel cut on the wafer 1 can be performed evenly in a circumferential direction of the wafer 1.

### Third Embodiment

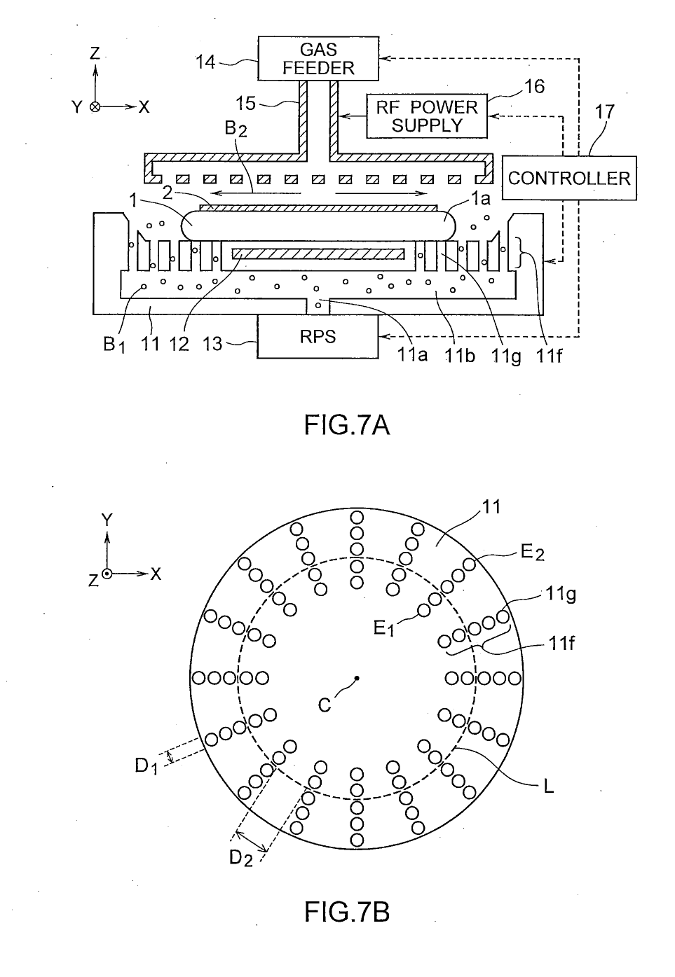

FIGS. 7A and 7B are a sectional view and a top view illustrating a structure of a semiconductor manufacturing apparatus of a third embodiment.

Similar to the first embodiment, the stage 11 of the present embodiment includes a hole 11a and a cavity 11b. The stage 11 of the present embodiment further includes a plurality of hole rows 11f.

FIG. 7B illustrates the upper face of the stage 11. The hole rows 11f are provided on the upper face of the stage 11, connected to the cavity 11b, and extend radially with respect to a center point C. Each hole row 11f includes a plurality of holes 11g arranged linearly. The holes 11g are an example of one or more openings.

Reference numerals E₁ and E₂ indicate an inner end portion and an outer end portion of each hole row 11f, respectively. In the present embodiment, the distance between the point C and the inner end portion E₁ of each hole row 11f is set smaller than the radius of the wafer 1. Moreover, the distance between the point C and the outer end portion E₂ of each hole row 11f is set larger than the radius of the wafer 1. This is similar to the case of each groove 11d of the first embodiment.

A reference numeral D₁ indicates a diameter of the holes 11g. The diameter D₁ is 1 mm, for example. A reference numeral D₂ indicates a distance between the hole rows 11f adjacent to each other in the circumferential direction. The distance D₂ is 4 mm, for example. Any number of the hole rows 11f may be provided on the upper face of the stage 11 as long as the bevel cut can be performed well.

According to the present embodiment, radicals from the hole rows 11f can be brought into contact with a bevel 1a even when the wafer 1 moves on the stage 11 or the center of the wafer 1 deviates from the center C of the stage 11, as with the first and second embodiments. As a result, according to the present embodiment, the position of the bevel cut on the wafer 1 can be stabilized as with the first and second embodiments.

While certain embodiments have been described, these embodiments have been presented by way of example only, and are not intended to limit the scope of the inventions. Indeed, the novel apparatuses and methods described herein may be embodied in a variety of other forms; furthermore, various omissions, substitutions and changes in the form of the apparatuses and methods described herein may be made without departing from the spirit of the inventions. The accompanying claims and their equivalents are intended to cover such forms or modifications as would fall within the scope and spirit of the inventions.

1. A semiconductor manufacturing apparatus comprising:
a wafer setting module including an upper face provided with one or more openings, a wafer being to be set on the upper face; and
a first particle supply module configured to supply first particles from the openings to an end portion of the wafer set on the wafer setting module to remove a film formed on the end portion of the wafer by using the first particles.

2. The apparatus of claim 1, wherein the first particles are radicals or plasma.

3. The apparatus of claim 1, further comprising a second particle supply module configured to supply second particles to the wafer set on the wafer setting module to form the film on the wafer by using the second particles.

4. The apparatus of claim 3, wherein the second particles are plasma.

5. The apparatus of claim 1, wherein the second particle supply module comprises a gas feeder configured to supply a second gas which is a source gas of the second particles when forming the film by using the second particles, and configured to supply a first gas to a surface of the film when removing the film by using the first particles.

6. The apparatus of claim 5, wherein the first gas is an inert gas.

7. The apparatus of claim 5, further comprising a controller configured to control a distance between a supply port supplying the first and second gases above the wafer and the wafer setting module.

8. The apparatus of claim 1, wherein the wafer is set on the upper face of the wafer setting module such that the openings include a first region covered with the wafer and a second region not covered with the wafer.

9. The apparatus of claim 1, wherein the openings include a plurality of grooves extending radially.

10. The apparatus of claim 9, wherein
the plurality of grooves extends radially with respect to a predetermined center point on the upper face of the wafer setting module,
a distance between the predetermined center point and inner end portions of the grooves is smaller than a radius of the wafer, and
a distance between the predetermined center point and outer end portions of the groove is larger than the radius of the wafer.

11. The apparatus of claim 9, wherein the openings further include an annular groove connected to outer end portions of the plurality of grooves and extending annularly.

12. The apparatus of claim 11, wherein a radius of an inner end portion of the annular groove is larger than a radius of the wafer.

13. The apparatus of claim 1, wherein the openings include a plurality of hole rows extending radially, each hole row including a plurality of holes arranged linearly.

14. The apparatus of claim 13, wherein
the plurality of hole rows extend radially with respect to a predetermined center point on the upper face of the wafer setting module,
a distance between the predetermined center point and inner end portions of the hole rows is smaller than a radius of the wafer, and
a distance between the predetermined center point and outer end portions of the hole rows is larger than the radius of the wafer.

15. A semiconductor manufacturing method comprising:
setting a wafer on an upper face of a wafer setting module, the upper face being provided with one or more openings; and
supplying first particles from the openings to an end portion of the wafer set on the wafer setting module to remove a film formed on the end portion of the wafer by using the first particles.

16. The method of claim 15, further comprising supplying second particles to the wafer set on the wafer setting module to form the film on the wafer by using the second particles.

17. The method of claim 16, further comprising:
supplying, from a gas feeder, a second gas which is a source gas of the second particles when forming the film by using the second particles, and
supplying, from the gas feeder, a first gas to a surface of the film when removing the film by using the first particles.

18. The method of claim 15, wherein the openings include a plurality of grooves extending radially.

19. The method of claim 18, wherein the openings further include an annular groove connected to outer end portions of the plurality of grooves and extending annularly.

20. The method of claim 15, wherein the openings include a plurality of hole rows extending radially, each hole row including a plurality of holes arranged linearly.
